(19) United States
(12) Patent Application Publication
(10) Pub. No.: US 2025/0183168 A1
(43) Pub. Date: Jun. 5, 2025

(54) SEMICONDUCTOR PACKAGE AND METHOD OF FORMING THE SAME

(71) Applicant: Taiwan Semiconductor Manufacturing Company, Ltd., Hsinchu (TW)

(72) Inventors: Wei-Chih Chen, Taipei City (TW); Po-Han Wang, Hsinchu City (TW); Yu-Hsiang Hu, Hsinchu City (TW); Hung-Jui Kuo, Hsinchu City (TW)

(73) Assignee: Taiwan Semiconductor Manufacturing Company, Ltd., Hsinchu (TW)

(21) Appl. No.: 18/528,812

(22) Filed: Dec. 5, 2023

(51) Int. Cl. H01L 23/528; H01L 21/60; H01L 21/768; H01L 23/498; H01L 23/522; H01L 23/544

(52) U.S. Cl. CPC H01L 23/5283; H01L 21/60; H01L 21/76898; H01L 23/49816; H01L 23/5226; H01L 23/544; H01L 2021/60075; H01L 2223/54426

(57) ABSTRACT

A semiconductor package and a method of forming the same are provided. The semiconductor package includes an interconnect structure, first connectors, a die, second connectors, a circuit board and a mark structure. The interconnect structure includes vias and lines stacked alternately and electrically connected to each other and embedded by polymer layers. The first connectors are disposed on a first side of the interconnect structure. The die is bonded to the first connectors. The second connectors are disposed on a second side of the interconnect structure. The circuit board is bonded to the second connectors. The mark structure is embedded in a first polymer layer among the polymer layers closest to the die and electrically insulated from the vias, the lines and the first connectors.

### BACKGROUND

The semiconductor integrated circuit (IC) industry has experienced rapid growth. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, such scaling down has also been accompanied by increased complexity in design and manufacturing of devices incorporating these ICs. Parallel advances in manufacturing have allowed increasingly complex designs to be fabricated with precision and reliability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1P are schematic cross-sectional views illustrating a method of forming a semiconductor package according to some embodiments of the present disclosure.

FIG. 2 is a schematic cross-sectional view illustrating a semiconductor package according to some embodiments of the present disclosure.

FIG. 3 is a simplified top view illustrating a carrier for forming a semiconductor package according to some embodiments of the present disclosure.

FIG. 4 is a simplified top view illustrating mark structures according to some embodiments of the present disclosure.

FIG. 5 is a simplified top view illustrating a first polymer layer according to some embodiments of the present disclosure.

FIG. 6 is a simplified enlarged top view of region R1 in FIG. 5.

FIG. 7 is a simplified enlarged side view of region R2 in FIG. 6.

FIG. 8 is a schematic cross-sectional view along a section line I-I′ in FIG. 6.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Advances in lithography have enabled the formation of increasingly complex circuits. In general, lithography is the formation of a pattern on a target. In one type of lithography, referred to as photolithography, radiation such as ultraviolet light passes through or reflects off a mask before striking a photoresist coating on the target. The photoresist includes one or more components that undergo a chemical transition when exposed to radiation. A resultant change in property allows either the exposed or the unexposed portions of the photoresist to be selectively removed. In this way, photolithography transfers a pattern from the mask onto the photoresist, which is then selectively removed to reveal the pattern. The target then undergoes processing steps (including a development process) that take advantage of the shape of the remaining photoresist to create features on the target.

Masks (i.e., photomasks) are used in many integrated circuit fabrication processes to expose a photoresist on an integrated circuit workpiece to light and, by selectively removing the exposed or unexposed regions of the photoresist, to selectively process corresponding portions of the workpiece. The amount of the workpiece that can be exposed by any given mask may depend on the mask size, the reticle size, and/or other properties of the mask or lithographic system (or exposure system) used to expose the workpiece. In many examples, the size of the exposed area sets a limit on the maximum size of an integrated circuit that can be formed using the mask and/or lithographic system. In order to fabricate a circuit that is larger than a given exposed area, some embodiments of the present disclosure provide a set of masks and a technique for exposing a single photoresist using different masks (e.g., two masks) at different locations.

In the present disclosure, mark structures (e.g., alignment marks) are formed to facilitate the subsequent alignment of the masks, so that features formed by the masks in a multiple-mask multiple-exposure process align correctly. Alignment of the masks may be verified and corrected by measuring the distances and/or skews between a first alignment feature formed by a first mask and a second alignment feature formed by a second mask, and suitable alignment feature patterns include box-in-box, cross-in-cross, test-line-type or other suitable alignment marks. Some examples provide two exposure systems with different field of views (or different overlay performance) and two different masks for the formation of integrated circuits that are larger than the exposed area of at least one of the two masks. In this way, exposure for larger package size is available. In addition, I/O densities can be increased, pitch/overlay limitation can be break through, wider enclosure window or higher overlay tolerance can be obtained, better overlay management can be provided, and/or price manufacturing time/cost can be ensured.

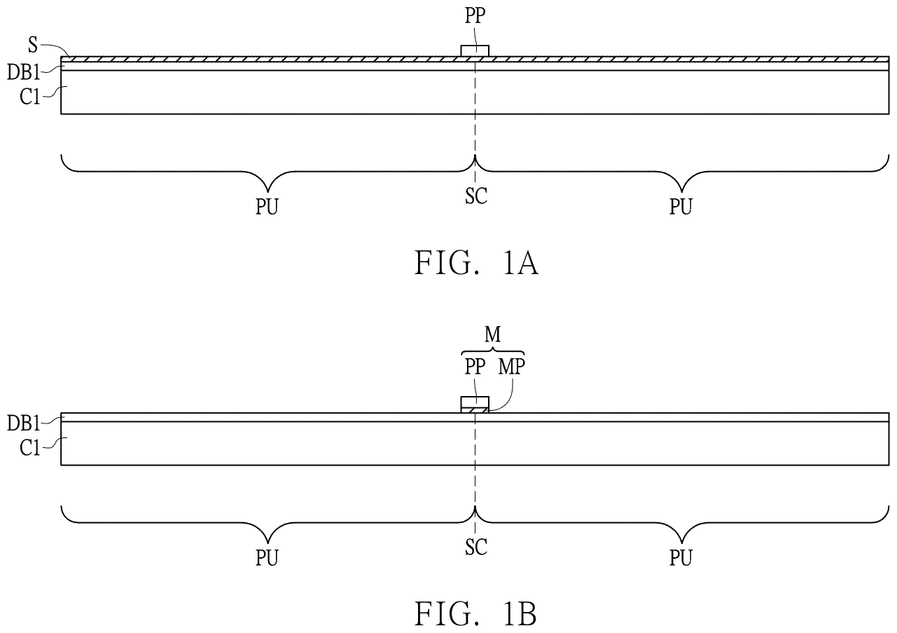

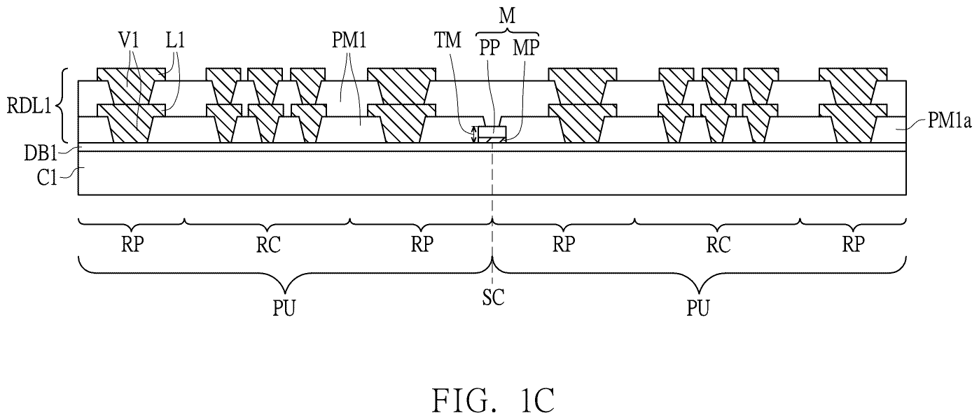

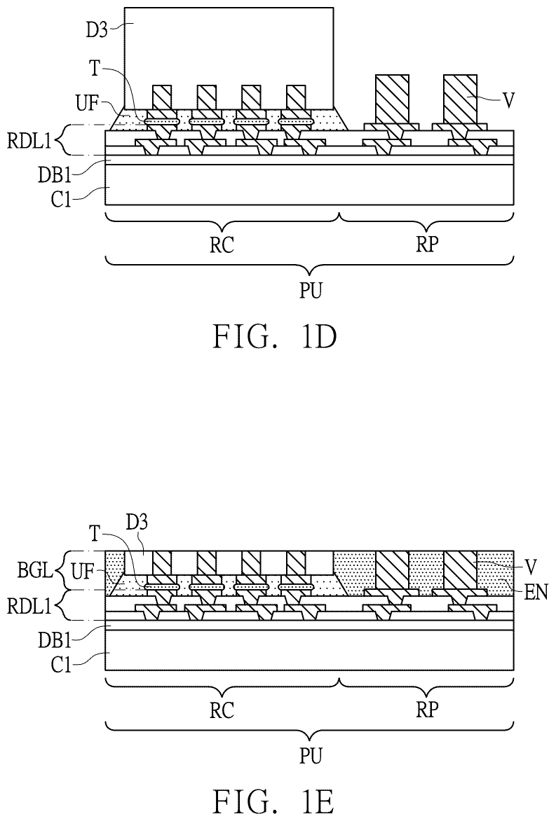

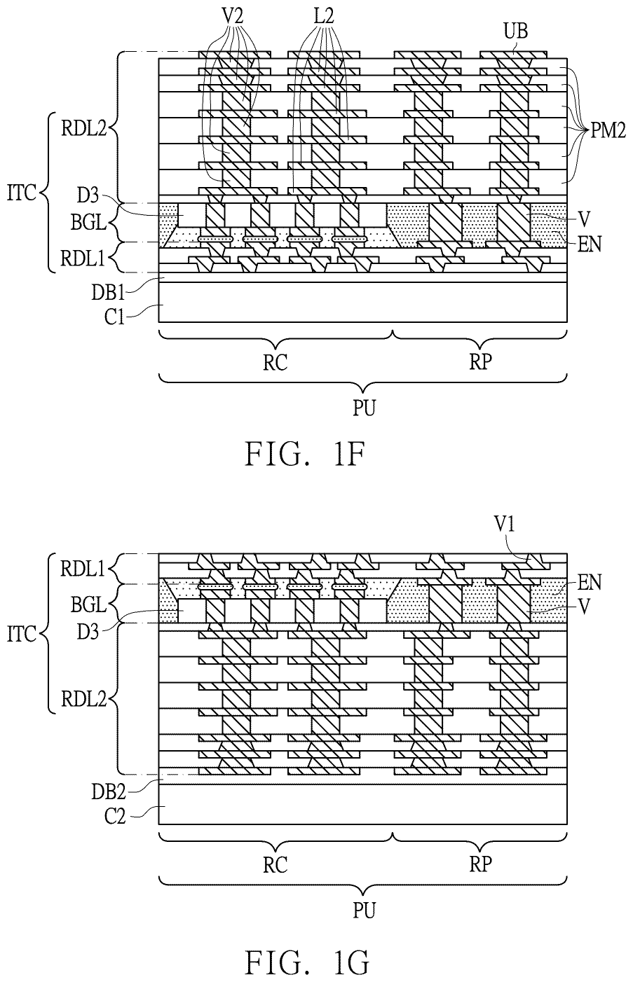

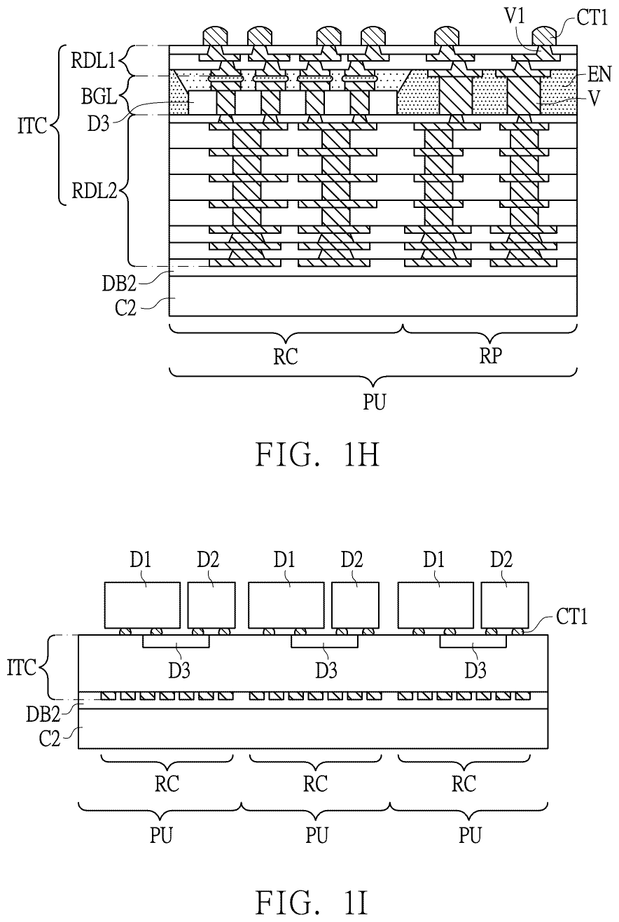

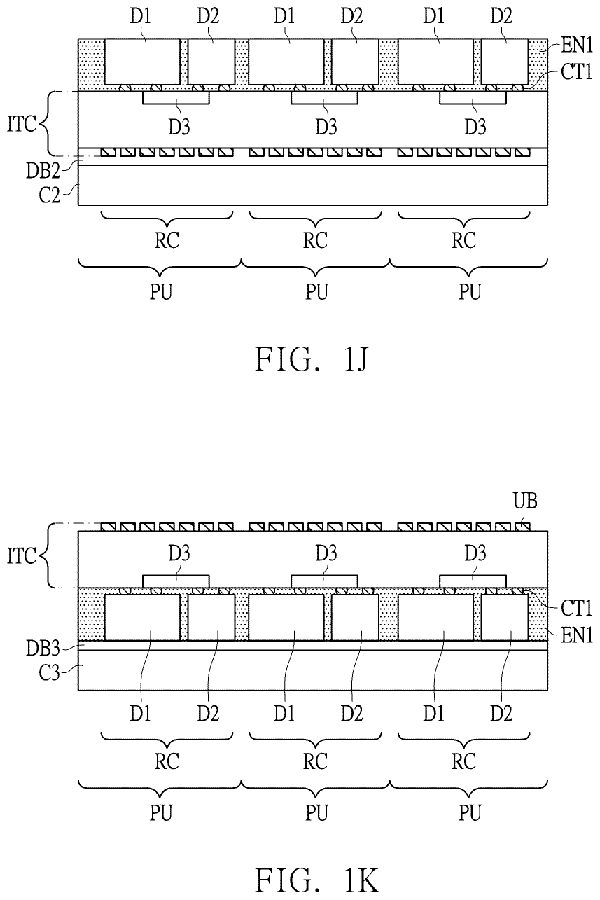

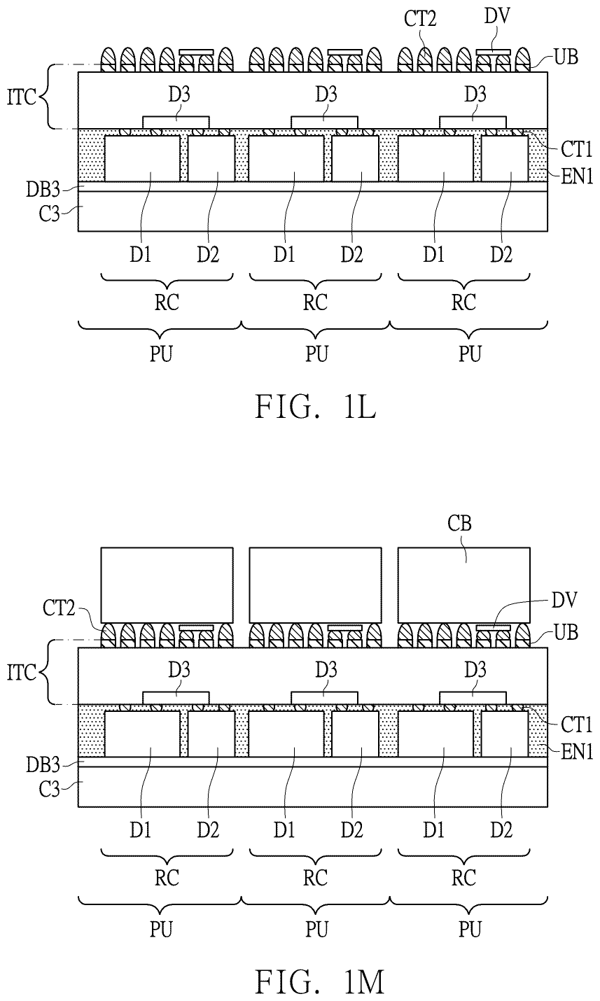

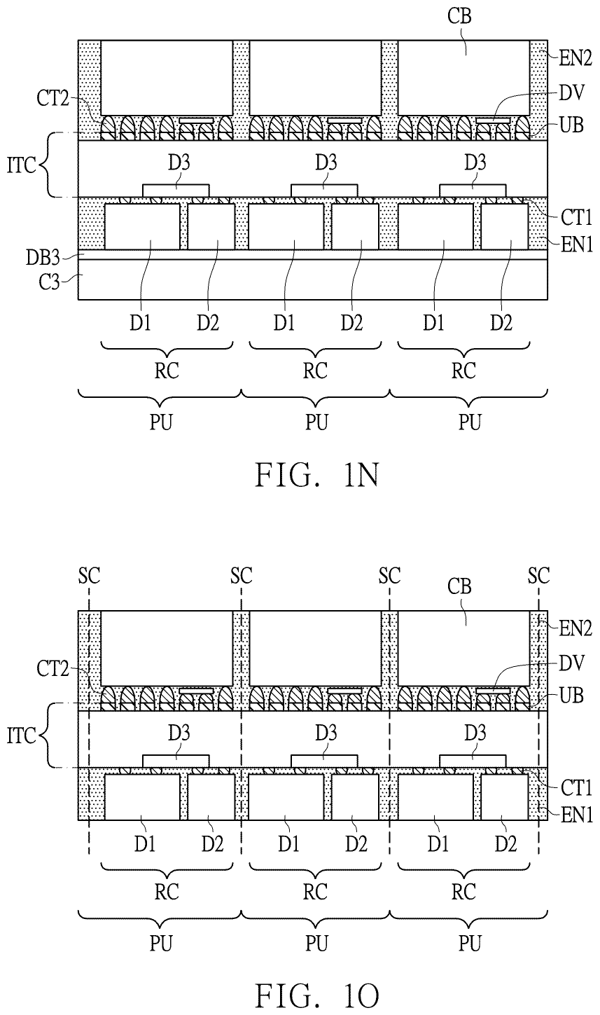

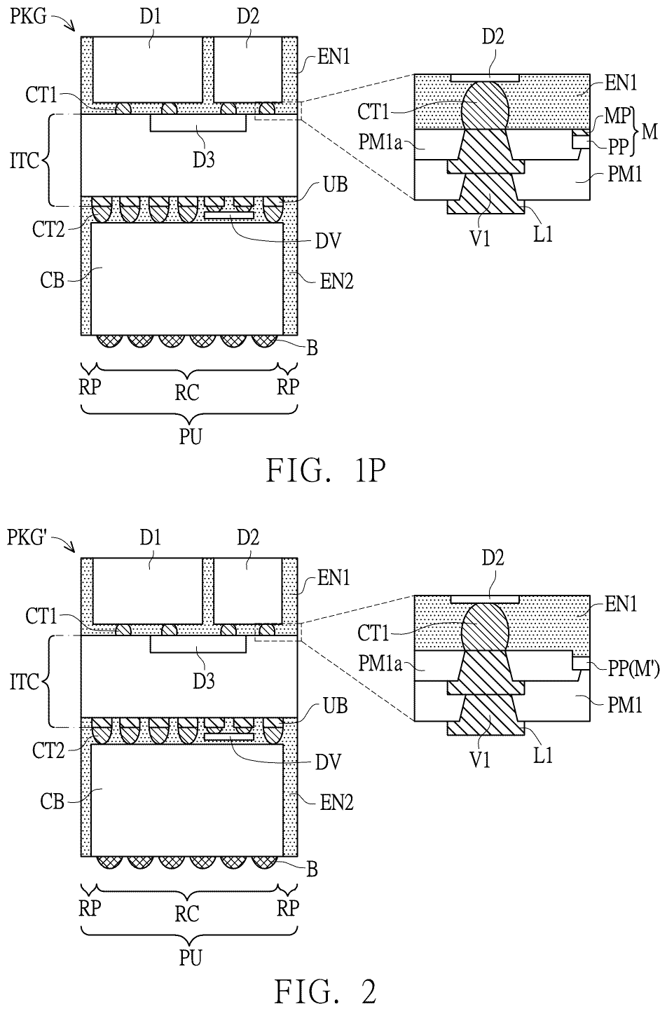

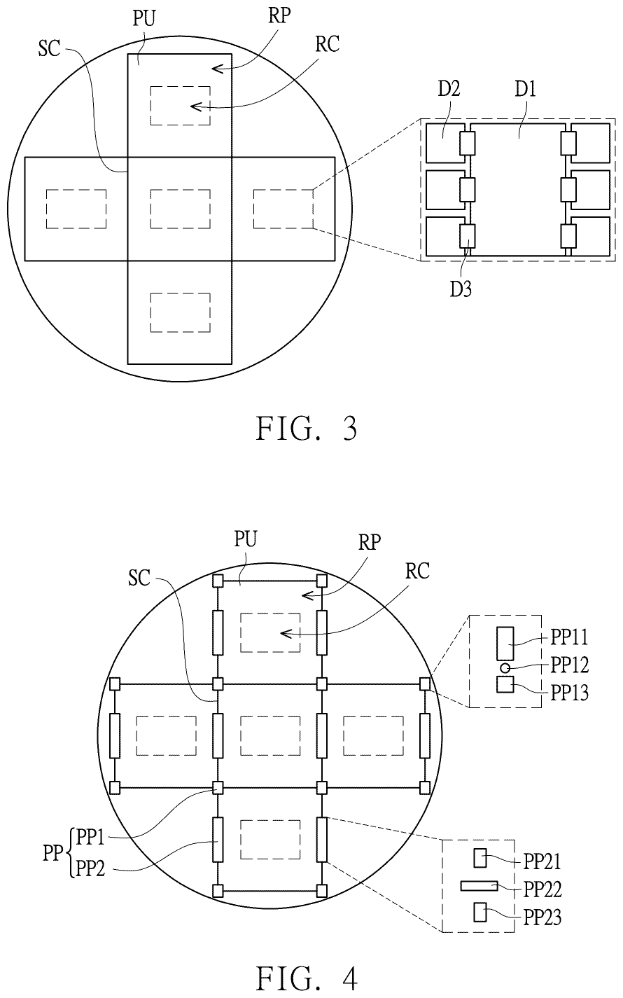

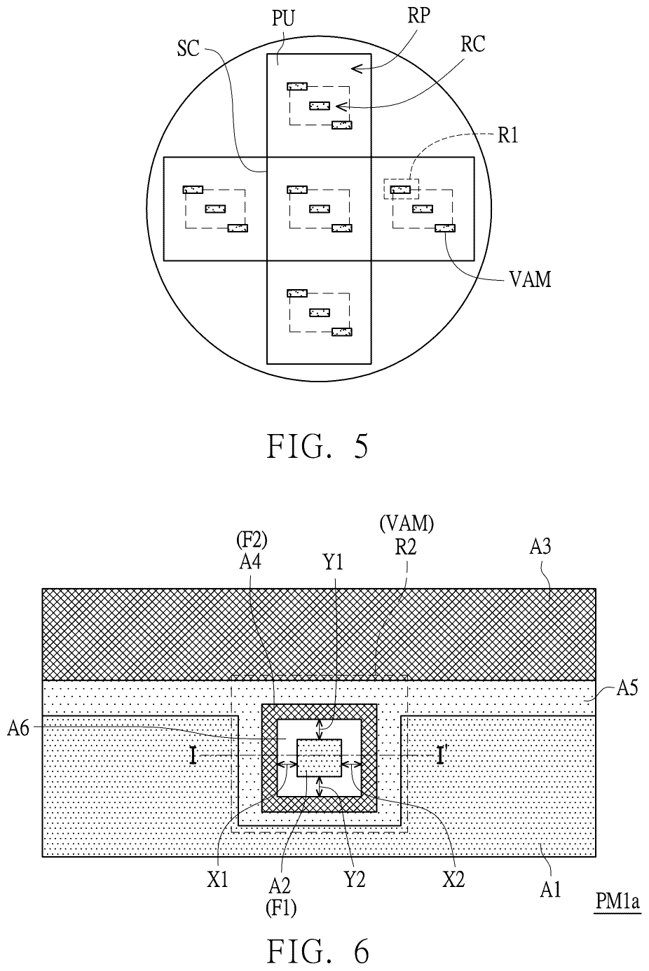

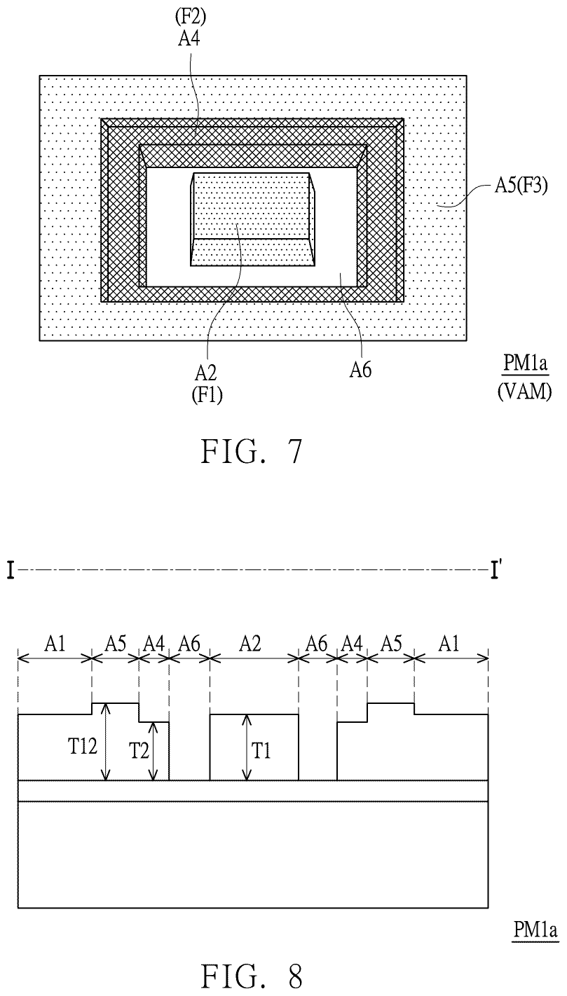

FIG. 1A to FIG. 1P are schematic cross-sectional views illustrating a method of forming a semiconductor package according to some embodiments of the present disclosure. FIG. 2 is a schematic cross-sectional view illustrating a semiconductor package according to some embodiments of the present disclosure. FIG. 3 is a simplified top view illustrating a carrier for forming a semiconductor package according to some embodiments of the present disclosure. FIG. 4 is a simplified top view illustrating mark structures according to some embodiments of the present disclosure. FIG. 5 is a simplified top view illustrating a first polymer layer according to some embodiments of the present disclosure. FIG. 6 is a simplified enlarged top view of region R1 in FIG. 5. FIG. 7 is a simplified enlarged side view of region R2 in FIG. 6. FIG. 8 is a schematic cross-sectional view along a section line I-I′ in FIG. 6.

Referring to FIG. 1A, a first carrier C1 is provided. In some embodiments, the first carrier C1 is a glass substrate, a metal plate, a plastic supporting board or the like, but other suitable substrate materials may be used as long as the materials are able to withstand the subsequent steps of the process. In some embodiments, a de-bonding layer DB1 may be formed over the first carrier C1. In some embodiments, the de-bonding layer DB1 includes a light-to-heat conversion (LTHC) release layer, which facilitates peeling the first carrier C1 away from the semiconductor package when required by the manufacturing process.

In some embodiments, the process may be performed at a reconstructed wafer level, so that multiple package units PU (or semiconductor package) are processed in the form of a reconstructed wafer. In the cross-sectional view of FIG. 1A, two package units PU are shown for simplicity. Besides, in the top view of FIG. 3, five package units PU are shown for simplicity. However, they are for illustrative purposes only, and the disclosure is not limited by the number of package units PU being produced in the reconstructed wafer. As shown in FIG. 3, each of the package units PU may have a chip region RC where dies (e.g., dies D1, D2 and D3) of the semiconductor package are subsequently formed and a periphery region RP surrounding the chip region RC and where periphery circuits (not shown), fan out wirings (not shown) or conductive vias (not shown) are subsequently formed.

Referring back to FIG. 1A, a seed layer S (or referred to as “a metal layer” or “a reflective layer”) is formed on the first carrier C1. In some embodiments, a material of the seed layer S includes a reflective material such as metal. The metal includes, for example, Cu, Al, Ti, Ta, W, Ru, Co, Ni, the like, or a combination thereof. Throughout the description, the term “copper (Cu)” is intended to include substantially pure elemental copper, copper containing unavoidable impurities, and copper alloys containing elements such as tantalum, indium, tin, zinc, manganese, chromium, titanium, germanium, strontium, platinum, magnesium, aluminum, or zirconium.

A plurality of polymer patterns PP (only one is shown in FIG. 1A) are formed on the seed layer S for patterning the seed layer S to form a plurality of metal patterns MP as shown in FIG. 1B (only one is shown in FIG. 1B). In some embodiments, a material of the polymer patterns PP includes transparent material, such as a photo-sensitive material. The photo-sensitive material includes, for example, polybenzoxazole (PBO), polyimide (PI), benzocyclobutene (BCB), the like, or a combination thereof. In some embodiments, the material of the polymer patterns PP may be replaced by dielectric materials or insulating materials as needed.

In some embodiments, the plurality of polymer patterns PP are located on scribe lanes SC between the package units PU. In some embodiments, as shown in FIG. 4, the plurality of polymer patterns PP include a plurality of first polymer patterns PP1 and a plurality of second polymer patterns PP2. In some embodiments, each of the plurality of first polymer patterns PP1 includes a plurality sub-patterns (e.g., a sub-pattern PP11, a sub-pattern PP12 and a sub-pattern PP13) having different shapes or sizes and arranged along scribe lanes SC between the package units PU. In some embodiments, each of the plurality of second polymer patterns PP2 includes a plurality sub-patterns (e.g., a sub-pattern PP21, a sub-pattern PP22 and a sub-pattern PP23) having different shapes, sizes or extension directions and arranged along scribe lanes SC between the package units PU. However, they are for illustrative purposes only, and the disclosure is not limited by the shape/location/number of the plurality of polymer patterns PP. In other embodiments, although not shown, the plurality of polymer patterns PP are located in the chip region RC, the periphery region RP or a combination of the above.

Referring back to FIG. 1A and FIG. 1B, the seed layer S is patterned with the plurality of polymer patterns PP to form a plurality of metal patterns MP, wherein each of the plurality of metal patterns MP is located under a corresponding polymer pattern PP, and orthogonal projections of the two patterns are the same. The set of one polymer pattern PP and an underlying metal pattern MP forms a mark structure M, and the mark structures M formed on the first carrier C1 may serve as alignment marks for alignment of the masks for subsequent formed polymer layer (e.g., a first polymer layer PM1a in FIG. 1C).

Referring to FIG. 1C, a first redistribution layer structure RDL1 is formed on the plurality of mark structures M and the first carrier CL. The first redistribution layer structure RDL1 includes a plurality of vias V1 and a plurality of lines L1 stacked alternately and electrically connected to each other and embedded by a plurality of polymer layers PM1. The formation of the first redistribution layer structure RDL1 includes sequentially forming more than one polymer layers and more than one metallization layers in alternation. In FIG. 1C, two polymer layers and two metallization layers are shown for simplicity but, of course, this is for illustrative purposes only, and the disclosure is not limited by the number of polymer layers and the number of metallization layers being produced in the first redistribution layer structure RDL1.

In some embodiments, a material of the plurality of polymer layers PM1 includes a photo-sensitive material such as polybenzoxazole (PBO), polyimide (PI), benzocyclobutene (BCB), the like, or a combination thereof. In some embodiments, the polymer layers PM1 may be formed by suitable fabrication techniques such as spin-on coating or the like and followed by patterning processes including a multiple-mask multiple-exposure process using two exposure systems with different field of views and two different masks and a development process.

For example, after the mark structures M are formed on the first carrier C1, a polymer material layer may be formed on the mark structures M and the first carrier C1 through spin-on coating, and then the polymer material layer can be subjected to a multiple-mask multiple-exposure process using the plurality of mark structures as alignment marks. Specifically, the polymer material layer in the plurality of package units PU may be exposed to light sequentially (or regionally) using a first exposure system having a smaller field of view (or smaller overlay variation) and a first mask having a light exposure region covering a single package unit PU, so that via openings having fine pitches can be defined in the chip regions RC of the plurality of package units PU via multiple light exposures. Taking FIG. 5 as an example, the first mask is placed over a first package unit among the plurality of package units PU to perform a light exposure process on the polymer material layer in the first package unit, and then the first mask is moved over a second package unit among the plurality of package units PU to perform another light exposure process on the polymer material layer in the second package unit. After the polymer material layer in the plurality of package units PU are subjected to light exposure, the first mask is removed. In other words, the first mask is moved four times to perform five light exposures to define via openings on the polymer material layer in the five package units PU. In addition, the polymer material layer in the plurality of package units PU may be once more exposed to light using a second exposure system having a larger field of view (or larger overlay variation) and a second mask having a light exposure region covering all the package units PU, so that via openings having coarse pitches can be defined in the periphery regions RP of the plurality of package units PU via one light exposure. Taking FIG. 5 as an example, the second mask is subjected to light exposure once to define via openings on the polymer material layer in the five package units PU. It should be understood that the order in which the first exposure system and the second exposure system are used is not limited.

After the multiple-mask multiple-exposure process for defining the via openings in the polymer material layer is completed, the polymer material layer is subjected to a development process to form the first polymer layer PM1a. Taking the negative-tone polyimide as an example, the greater the amount of light irradiation or the longer the light exposure time, the thicker the thickness after development. In FIG. 6, regions A1 and A2 of the first polymer layer PM1a were exposed by light from the first exposure system, regions A3 and A4 of the polymer material layer were exposed by light from the second exposure system, region A5 of the polymer material layer was exposed by light from both of the first exposure system and the second exposure system, while region A6 of the polymer material layer was not exposed by light from any of the first exposure system and the second exposure system. Therefore, as shown in FIG. 8, a thickness T12 of the first polymer layer PM1a corresponding to the region A5 subject to light irradiation twice is larger than a thickness (e.g., a thickness T1 or a thickness T2) of the first polymer layer PM1a corresponding to regions (e.g., regions A1, A2, A3 and A4) subject to light irradiation once. In some embodiments, the amount of light from the first exposure system can be different from the amount of light from the second exposure system, and/or the light exposure time of the first exposure system can be different from the light exposure time of the second exposure system. In such embodiments, the thickness T1 is not equal to the thickness T2. However, in some alternative embodiments, the thickness T1 is equal to the thickness T2.

As shown in FIG. 5 through FIG. 8, by pattern design of the first mask and the second mask, alignment of the masks may be verified and corrected by measuring the distances (e.g., distances X1, X2, Y1 and Y2) and/or skews between features formed by the first mask and the second mask. For example, the first polymer layer PM1a may include a plurality of verification alignment masks VAM in the chip region RC of the semiconductor package (see package unit PU in FIG. 5), each of the plurality of verification alignment masks VAM includes a first alignment feature F1 formed by the first mask and a second alignment feature F2 formed by the second mask. The horizontal offset between the masks may be verified and corrected by measuring the distances X1 and X2 between the first alignment feature F1 and the second alignment feature F2. In addition, the vertical offset between the masks may be verified and corrected by measuring the distances Y1 and Y2 between the first alignment feature F1 and the second alignment feature F2. Moreover, the skews between the masks may be verified and corrected by measuring parallelism of corresponding sides of the first alignment feature F1 and the second alignment feature F2, but not limited thereto. In some embodiments, as shown in FIG. 7, the first alignment feature F1 is an island-shaped pattern, and the second alignment feature F2 is a frame-shaped pattern, wherein the island-shaped pattern is surrounded by the frame-shaped pattern. In some embodiments, each of the plurality of verification alignment masks VAM further includes a third alignment feature F3 formed by the first mask and the second mask. In some embodiments, the third alignment feature F3 is a frame-shaped pattern, and the frame-shaped pattern of the second alignment feature F2 is surrounded by the frame-shaped pattern of the third alignment feature F3. In addition, a thickness (e.g., the thickness T12) of the frame-shaped pattern of the third alignment feature F3 is larger than a thickness (e.g., the thickness T1) of the island-shaped pattern of the first alignment feature F1, and a thickness TM (shown in FIG. 1C) of the plurality of mark structures (M) is smaller than the thickness (e.g., the thickness T1) of the island-shaped pattern of the first alignment feature F1. In some embodiments, the thickness TM (shown in FIG. 1C) of the plurality of mark structures (M) is smaller than a minimum thickness (e.g., the thickness T2 in FIG. 8) of the first alignment feature FL.

Referring back to FIG. 1C, a first layer of metal features (including the plurality of vias V1 and the plurality of lines L1) closest to the first carrier C1 is formed after the first polymer layer PM1a is formed. In some embodiments, a material of the metal features includes Cu, Al, Ti, Ta, W, Ru, Co, Ni, the like, or a combination thereof. In some embodiments, although not shown, a metal liner layer may be disposed between each metal feature and the polymer layer (first polymer layer PM1a). In some embodiments, the metal liner layer includes a seed layer and/or a barrier layer. The seed layer may include Ti/Cu. The barrier layer may include Ta, TaN, Ti, TiN, CoW or a combination thereof. In some embodiments, the first redistribution layer structure RDL1 is formed by a dual damascene process. For example, a metal line and the underlying metal via may be formed as an integrated line and via structure without an interface by a dual damascene process.

For example, metal features are formed by lining via openings of the first polymer layer PM1a with a seed layer, forming a photoresist layer with openings on the seed layer, plating the metal features from the seed layer, and removing the photoresist layer and the underlying seed layer. In some embodiments, the via openings of the first polymer layer PM1a are controlled properly (e.g., less than about 10 μm or 5 μm), so the formed vias V1 may have planar top surfaces for the landing of the overlying vias V1. Another polymer layer (the polymer layer PM1 over the first polymer layer PM1a) is then formed on the first polymer layer PM1a. The method of forming the polymer layer PM1 over the first polymer layer PM1a is similar to the method of forming the first polymer layer PM1a, and thus the detail is omitted herein. A second layer of metal features (including the plurality of vias V1 and the plurality of lines L1) away from the first carrier C1 is subsequently formed. The method of forming the second layer of metal features is similar to the method of forming the first layer of metal features, and thus the detail is omitted herein.

Referring to FIG. 1D, a plurality of conductive vias V and a plurality of bridge dies (e.g., dies D3; only one die D3 is shown in FIG. 1D) are provided on the first redistribution layer structure RDL1.

In some embodiments, the plurality of conductive vias V may be formed by filling the openings of a patterned mask (not shown) with conductive material. In some embodiments, the conductive material of the plurality of conductive vias V includes cobalt (Co), tungsten (W), copper (Cu), titanium (Ti), tantalum (Ta), aluminum (Al), zirconium (Zr), hafnium (Hf), a combination thereof, or other suitable metallic materials. In some embodiments, the conductive material may be formed by a plating process. The plating process may be, for example, electro-plating, electroless-plating, immersion plating, or the like. In some embodiments, the conductive material may be deposited on a seed layer (not shown). In some embodiments, the formation of the seed layer may be skipped, as the topmost metal features of the first redistribution layer structure RDL1 can seed the deposition of the conductive material. However, the disclosure is not limited thereto. In some alternative embodiments, other suitable methods may be utilized to form the conductive vias V. For example, pre-fabricated conductive vias V (e.g., pre-fabricated conductive pillars) may be picked-and-placed and bonded onto the first redistribution layer structure RDL1.

In some embodiments, the plurality of bridge dies (e.g., dies D3) are disposed on the first redistribution layer structure RDL1 in between the plurality of conductive vias V. The plurality of bridge dies (e.g., dies D3) are bonded to some of the plurality of lines L1 of the first redistribution layer structure RDL1. In some embodiments, although not shown, the die D3 includes a semiconductor substrate, having through semiconductor vias (TSVs) and interconnection conductive patterns formed therethrough. A dielectric layer may be disposed at a bottom surface of the die D3, closer to the first redistribution layer structure RDL1. The semiconductor substrate may be made of suitable semiconductor materials, such as semiconductor materials of the groups III-V of the periodic table. In some embodiments, the semiconductor substrate includes elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide. The interconnection conductive patterns are in electrical contact with conductive terminals T formed on the dielectric layer at the bottom surface of the die D3. The conductive terminals T may be micro-bumps. For example, the conductive terminals T may include a conductive post and a solder cap disposed on the conductive post. In some embodiments, the conductive posts may be copper posts. However, the disclosure is not limited thereto, and other conductive structures such as solder bumps or metallic bumps (e.g., gold bumps) may also be used as the conductive terminals T. In some embodiments, the die D3 is disposed with the bottom surface directed towards the first redistribution layer structure RDL1 so that the conductive terminals T can be bonded to the first redistribution layer structure RDL1. The conductive terminals T may be bonded to the first redistribution layer structure RDL1 through a reflow process, for example.

In some embodiments, an underfill UF may be disposed between the plurality of bridge dies (e.g., dies D3) and the first redistribution layer structure RDL1 to protect the conductive terminals T against thermal or physical stresses and secure the electrical connection of the plurality of bridge dies (e.g., dies D3) with the first redistribution layer structure RDL1. In some embodiments, the underfill UF is formed by capillary underfill filling (CUF). A dispenser (not shown) may apply a filling material (not shown) along the perimeter of each of the plurality of bridge dies (e.g., dies D3). In some embodiments, a curing process is performed to consolidate the underfill UF.

In some embodiments, a thinning process may be performed on the plurality of bridge dies (e.g., dies D3) to reduce the thickness of the plurality of bridge dies (e.g., dies D3) before encapsulating the plurality of bridge dies (e.g., dies D3) and the plurality of conductive vias V. The thinning process may include a mechanical grinding process and/or a chemical mechanical polishing (CMP) process, but not limited thereto.

Referring to FIG. 1E, an encapsulant EN is formed on the first redistribution layer structure RDL1, encapsulating the plurality of conductive vias V and the plurality of bridge dies (e.g., dies D3). In some embodiments, a material of the encapsulant EN includes a molding compound, a polymeric material, such as polyimide, epoxy resin, acrylic resin, phenol resin, benzocyclobutene (BCB), polybenzooxazole (PBO), a combination thereof, or other suitable polymer-based dielectric materials. In some embodiments, the encapsulant EN may be formed through an over-molding process (e.g., a compression molding process), initially covering the plurality of conductive vias V and the plurality of bridge dies (e.g., dies D3), and may be subsequently thinned until the plurality of conductive vias V and the plurality of bridge dies (e.g., dies D3) are exposed. For example, a planarization process may be performed removing portions of the encapsulant EN and, if needed, of the plurality of bridge dies and/or of the plurality of conductive vias V from the side of the top surfaces. In some embodiments, the planarization of the encapsulant EN includes performing a mechanical grinding process and/or a chemical mechanical polishing (CMP) process. Following planarization, the top surfaces of the plurality of conductive vias V, the top surfaces of the plurality of bridge dies (e.g., dies D3), and the top surface of the encapsulant EN may be substantially flush with respect to each other (be at substantially the same level height, coplanar with respect to each other). In some embodiments, the plurality of conductive vias V, the plurality of bridge dies (e.g., dies D3), and the encapsulant EN are considered parts of a bridging layer BGL stacked on the first redistribution layer structure RDL1.

Referring to FIG. 1F, a second redistribution layer structure RDL2 is formed on the bridging layer BGL. The second redistribution layer structure RDL2 includes a plurality of vias V2 and a plurality of lines L2 stacked alternately and electrically connected to each other and embedded by a plurality of polymer layers PM2. Optionally, the second redistribution layer structure RDL2 further includes a plurality of under-bump metallurgies UB on a side of the second redistribution layer structure RDL2 away from the bridging layer BGL. The second redistribution layer structure RDL2 may have a similar structure and be formed following similar processes as the ones previously described for the first redistribution layer structure RDL1 except that the alignment of the masks for patterning the bottommost polymer layer among the plurality of polymer layers PM2 uses the topmost metal features (e.g., TSVs or interconnection conductive patterns in the dies D3 and/or the plurality of conductive vias V) of the bridging layer BGL as alignment marks. In some embodiments, the topmost polymer layer PM2 is patterned to expose the underlying metal features (e.g., the topmost vias V2). The under-bump metallurgies UB are optionally conformally formed in the openings of the (topmost) polymer layer PM2 exposing the metal features, and may further extend over portions of the exposed surface of the (topmost) polymer layer PM2. In some embodiments, the under-bump metallurgies UB include multiple stacked layers of conductive materials. For example, the under-bump metallurgies UB may include one or more metallic layers stacked on a seed layer. In some embodiments, the second redistribution layer structure RDL2, the bridging layer BGL, and the first redistribution layer structure RDL1 may collectively be referred to as an interconnect structure ITC.

Referring to FIG. 1G, a second carrier C2 may be bonded on the second redistribution layer structure RDL2. In some embodiments, a de-bonding layer DB2 may be formed over the second carrier C2 before the second carrier C2 is bonded on the second redistribution layer structure RDL2. In some embodiments, the de-bonding layer DB2 includes a light-to-heat conversion (LTHC) release layer, which facilitates peeling the second carrier C2 away from the semiconductor package when required by the manufacturing process.

After bonding of the second carrier C2, the reconstructed wafer may be overturned and the first carrier C1 may be removed to expose the first redistribution layer structure RDL1 for further processing. When the de-bonding layer DB1 is included, the de-bonding layer DB1 may be irradiated with a UV laser so that the first carrier C1 and the de-bonding layer DB1 are easily peeled off from the reconstructed wafer. Nevertheless, the de-bonding process is not limited thereto, and other suitable de-bonding methods may be used in some alternative embodiments.

Although not shown in FIG. 1G, the plurality of metal patterns MP shown in FIG. 1C of the plurality of mark structures M as well as the vias V1 closest to the first carrier C1 are exposed/revealed when the first carrier C1 is de-bonded. In some embodiments, the plurality of metal patterns MP are removed (e.g., through an etching process) to expose the plurality of polymer patterns PP (shown in FIG. 1C) of the plurality of mark structures M, but not limited thereto.

Referring to FIG. 1H, a plurality of first connectors CT1 are formed on a first side (e.g., upper side of the interconnect structure ITC in FIG. 1H) of the interconnect structure ITC, wherein the plurality of mark structures M are electrically insulated from the plurality of first connectors CT1. Specifically, the plurality of first connectors CT1 are electrically connected to the vias V1 that are exposed/revealed after the first carrier C1 is de-bonded.

In some embodiments, under-bump metallurgies (not shown) may be optionally formed, in contact with the exposed/revealed vias V1, before providing the plurality of first connectors CT1 on the interconnect structure ITC. The plurality of first connectors CT1 may be formed on the under-bump metallurgies (if included) or the exposed portions of the vias V1. In some embodiments, the plurality of first connectors CT1 are attached to the under-bump metallurgies through a solder flux. In some embodiments, the plurality of first connectors CT1 are controlled collapse chip connection (C4) bumps. In some embodiments, the plurality of first connectors CT1 include a conductive material with low resistivity, such as Sn, Pb, Ag, Cu, Ni, Bi, or an alloy thereof.

Referring to FIG. 1I, a plurality of dies (semiconductor dies) D1 and D2 are disposed side by side over the interconnect structure ITC with a pick-and-place process. In some embodiments, the plurality of dies D1 and D2 may include different types of dies or the same types of dies. In some embodiments, the plurality of dies D1 and D2 may include one or more types of chips selected from application-specific integrated circuit (ASIC) chips, analog chips, sensor chips, wireless and radio frequency chips, voltage regulator chips or memory chips. In some embodiments, the plurality of dies D1 and D2 may have different sizes, include different components, and/or include components of different sizes. For example, the plurality of dies D1 and D2 may differ in the number of chips included. In some embodiments, each of the plurality of dies D1 may independently be or include a logic die, such as a central processing unit (CPU) die, a graphic processing unit (GPU) die, a micro control unit (MCU) die, an input-output (I/O) die, a baseband (BB) die, or an application processor (AP) die. In some embodiments, each of the plurality of dies D1 may independently be or include a memory die.

In some embodiments, the plurality of bridge dies (e.g., dies D3) of the interconnect structure ITC electrically connect the dies D1 and D2 of a same package unit PU. That is, electrical connection between the dies D1 and D2 is established through the plurality of bridge dies (e.g., dies D3) of the interconnect structure ITC. For example, each die D3 electrically connects a die D1 with adjacent die D2 via the plurality of first connectors CT1, the first redistribution layer structure RDL1 (shown in FIG. 1H), the second redistribution layer structure RDL2 (shown in FIG. 1H) and the plurality of conductive vias V (shown in FIG. 1H). In some embodiments, the first redistribution layer structure RDL1 does not directly interconnect the dies D1 and D2. In some embodiments, where a gap exists between adjacent dies D1 and D2, the die D3 extends over such gap. In some embodiments, the die D3 functions as an interconnecting structure for adjacent dies D1 and D2 and provides shorter electrical connection paths between the adjacent dies D1 and D2.

Referring to FIG. 1J, a first encapsulant EN1 is formed over the interconnect structure ITC to encapsulate the plurality of dies D1 and D2. The first encapsulant EN1 laterally encircles the plurality of dies D1 and D2, extending also in the gaps in between the plurality of dies D1 and D2. In some embodiments, the material of the first encapsulant EN1 may be selected as described above for the encapsulant EN. The first encapsulant EN1 may be formed by a sequence of over-molding and planarization steps. For example, the first encapsulant EN1 may be originally formed by a molding process (such as a compression molding process) or a spin-coating process to completely cover the plurality of dies D1 and D2. In some embodiments, the planarization of the first encapsulant EN1 includes performing a mechanical grinding process and/or a chemical mechanical polishing (CMP) process. In some embodiments, the planarization process is performed until the rear surfaces (e.g., the top surfaces of the plurality of dies D1 and D2 in FIG. 1J) of the plurality of dies D1 and D2 are exposed. In some embodiments, following the planarization process, the rear surfaces of the plurality of dies D1 and D2 and the top surface of the first encapsulant EN1 may be substantially at a same level height (be substantially coplanar).

Referring to FIG. 1K, a third carrier C3 may be bonded on the plurality of dies D1 and D2 and the first encapsulant EN1. In some embodiments, a de-bonding layer DB3 may be formed over the third carrier C3 before the third carrier C3 is bonded on the plurality of dies D1 and D2 and the first encapsulant EN1. In some embodiments, the de-bonding layer DB3 includes a light-to-heat conversion (LTHC) release layer, which facilitates peeling the third carrier C3 away from the semiconductor package when required by the manufacturing process.

After bonding of the third carrier C3, the reconstructed wafer may be overturned and the second carrier C2 may be removed to expose the plurality of under-bump metallurgies UB for further processing. When the de-bonding layer DB2 is included, the de-bonding layer DB2 may be irradiated with a UV laser so that the second carrier C2 and the de-bonding layer DB2 are easily peeled off from the reconstructed wafer. Nevertheless, the de-bonding process is not limited thereto, and other suitable de-bonding methods may be used in some alternative embodiments.

Referring to FIG. 1L, a plurality of devices DV are bonded to connection pads (not labeled) of the interconnect structure ITC through micro-bumps (not labeled), and a plurality of second connectors CT2 are placed on and electrically connected to the plurality of under-bump metallurgies UB located on a second side of the interconnect structure ITC. The second side of the interconnect structure ITC is opposite to the first side of the interconnect structure ITC. Namely, the plurality of first connectors CT1 and the plurality of second connectors CT2 are respectively located on opposite sides of the interconnect structure ITC. Even though only three devices DV are presented in FIG. 1M for illustrative purposes, the disclosure is not limited by the number of devices DV. In some embodiments, the plurality of devices DV are integrated passive devices (IPD) including resistors, capacitors, inductors, resonators, filters, and/or the like. In other embodiments, the plurality of devices DV can be integrated active devices (IAD) upon the process requirements.

In some embodiments, the micro-bumps and the plurality of second connectors CT2 may be solder bumps, and/or may include metal pillars (e.g., copper pillars), solder caps formed on metal pillars, and/or the like. When solder is used, the solder may include either eutectic solder or non-eutectic solder. The solder may include lead or be lead-free, and may include Sn—Ag, Sn—Cu, Sn—Ag—Cu, or the like. The micro-bumps and the plurality of second connectors CT2 may be formed respectively by a suitable process such as evaporation, electroplating, ball drop, or screen printing.

Referring to FIG. 1M, a plurality of circuit boards CB are bonded to the plurality of second connectors CT2. In some embodiments, a soldering step may be performed. In some embodiments, the plurality of circuit boards CB are printed circuit boards or flexible printed circuit boards. In some embodiments, although not shown, an underfill may optionally be provided in between the interconnect structure ITC and the plurality of circuit boards CB. The underfill may laterally wrap the plurality of second connectors CT2, for example, to protect the plurality of second connectors CT2 from mechanical stresses.

Referring to FIG. 1N, a second encapsulant EN2 is formed over the interconnect structure ITC to encapsulate the plurality of circuit boards CB. The second encapsulant EN2 laterally encircles the plurality of circuit boards CB, extending also in the gaps in between the plurality of circuit boards CB. In some embodiments, the material of the second encapsulant EN2 may be selected as described above for the encapsulant EN. The second encapsulant EN2 may be formed by a sequence of over-molding and planarization steps. For example, the second encapsulant EN2 may be originally formed by a molding process (such as a compression molding process) or a spin-coating process to completely cover the plurality of circuit boards CB. In some embodiments, the planarization of the second encapsulant EN2 includes performing a mechanical grinding process and/or a chemical mechanical polishing (CMP) process. In some embodiments, the planarization process is performed until the top surfaces of the plurality of circuit boards CB are exposed. In some embodiments, following the planarization process, the top surfaces of the plurality of circuit boards CB and the top surface of the second encapsulant EN2 may be substantially at a same level height (be substantially coplanar).

Referring to FIG. 1O and FIG. 1P, a singulation process is performed to separate the individual package units PU into a plurality of semiconductor package PKG, for example, by cutting along the scribe lanes SC arranged between individual package units PU. In some embodiments, the singulation process typically involves performing a wafer dicing process with a rotating blade and/or a laser beam. In some embodiments, the third carrier C3 is separated from the plurality of semiconductor packages PKG before or after the singulation process. When the de-bonding layer DB3 is included, the de-bonding layer DB3 may be irradiated with a UV laser so that the third carrier C3 and the de-bonding layer DB3 are easily peeled off from the reconstructed wafer. Nevertheless, the de-bonding process is not limited thereto, and other suitable de-bonding methods may be used in some alternative embodiments. In some embodiments, a plurality of conductive terminals B are formed on the circuit board CB before or after the singulation process. In some embodiments, the conductive terminals B are formed in contact openings of a dielectric layer (not shown) in the circuit board CB through a ball placement process, and the conductive terminals B include lead-free solder balls, solder balls, ball grid array (BGA) balls, bumps, C4 bumps or micro bumps.

It is understood that the disclosure is not limited by the method described above. Additional operations can be provided before, during, and/or after the method and some of the operations described above can be replaced or eliminated, for additional embodiments of the methods.

Referring to FIG. 1P, a semiconductor package PKG according to some embodiments of the disclosure includes an interconnect structure ITC, a plurality of first connectors CT1, a plurality of dies D1 and D2, a plurality of second connectors CT2, a circuit board CB and a plurality of mark structures M (only one is shown in FIG. 1P). The interconnect structure ITC includes a plurality of vias V1 and a plurality of lines L1 stacked alternately and electrically connected to each other and embedded by a plurality of polymer layers PM1. The plurality of first connectors CT1 are disposed on a first side (e.g., an upper side of the interconnect structure ITC in FIG. 1P) of the interconnect structure ITC. The plurality of dies D1 and D2 are bonded to the plurality of first connectors CT1. The plurality of second connectors CT2 are disposed on a second side (e.g., a lower side of the interconnect structure ITC in FIG. 1P) of the interconnect structure ITC. The circuit board CB is bonded to the plurality of second connectors CT2. The plurality of mark structures M are embedded in a first polymer layer PM1a among the plurality of polymer layers PM1 closest to the plurality of dies D1 and D2 and electrically insulated from the plurality of vias V1, the plurality of lines L1 and the plurality of first connectors CT1.

In some embodiments, each of the plurality of mark structures M is a stack of two patterns (e.g., a metal pattern MP and a polymer pattern PP) respectively formed of a reflective material and a transparent material, and orthogonal projections of the two patterns are the same. In some embodiments, the two patterns are a metal pattern MP and a polymer pattern PP, and the metal pattern MP is closer to the plurality of dies D1 and D2 than the polymer pattern PP. In some embodiments, a surface of the metal pattern MP facing the plurality of dies D1 and D2 is leveled with a surface of the first polymer layer PM1a facing the plurality of dies. In some embodiments, a surface (e.g., top surface) of the polymer pattern PP facing the plurality of dies D1 and D2 is indented from (not leveled with) a surface (e.g., top surface) of the first polymer layer PM1a facing the plurality of dies, and a surface (e.g., bottom surface) of the polymer pattern PP facing away from the plurality of dies D1 and D2 is indented from (not leveled with) a surface (e.g., bottom surface) of the first polymer layer PM1a facing away from the plurality of dies D1 and D2. In some embodiments, as shown in FIG. 7 and FIG. 8, the first polymer layer PM1a includes a plurality of island-shaped patterns (see “F1” in FIG. 7) and a plurality of frame-shaped patterns (see “F3” in FIG. 7) in a chip region RC of the semiconductor package PKG, and the plurality of island-shaped patterns are respectively surrounded by the plurality of frame-shaped patterns. In some embodiments, a thickness (see “T12” in FIG. 8) of the frame-shaped patterns is larger than a thickness (see “T1” in FIG. 8) of the island-shaped patterns, and a thickness (see “TM” in FIG. 1C) of the plurality of mark structures M is smaller than the thickness (see “T1” in FIG. 8) of the island-shaped patterns.

In some embodiments, as shown in FIG. 1P, each of the plurality of mark structures M includes a polymer pattern PP having a thickness smaller than a thickness of the first polymer layer PM1a. The thickness of the first polymer layer PM1a refers to the minimum thickness of the first polymer layer PM1a when the first polymer layer PM1a has a plurality of thicknesses (e.g., the thicknesses T1, T2 and T12 shown in FIG. 8). In some embodiments, each of the plurality of mark structures M further includes a metal pattern MP, and orthogonal projections of the metal pattern MP and the polymer pattern PP are the same. In some embodiments, the semiconductor package PKG has a chip region RC and a periphery region RP surrounding the chip region RC, and the plurality of mark structures M are located in the chip region RC, the periphery region RP (as shown in FIG. 1P) or a combination of the above. In some embodiments, as shown in FIG. 1H, the interconnect structure ITC includes a first redistribution layer structure RDL1, a plurality of bridge dies (dies D3; only one is shown in FIG. 1H), a plurality of conductive vias V, and a second redistribution layer structure RDL2, and wherein the plurality of bridge dies (dies D3) and the plurality of conductive vias V are located between the first redistribution layer structure RDL1 and the second redistribution layer structure RDL2, the plurality of first connectors CT1 are located between the first redistribution layer structure RDL1 and the plurality of dies D1 and D2 (as shown in FIG. 1H and FIG. 1I), and the plurality of second connectors CT2 are located between the second redistribution layer structure RDL2 and the circuit board CB (as shown in FIG. 1H and FIG. 1P).

Referring to FIG. 2, a semiconductor package PKG′ according to some other embodiments of the disclosure is provided. In the semiconductor package PKG′, each of the plurality of mark structures M′ includes a polymer pattern PP and does not include the metal pattern MP shown in FIG. 1P. Specifically, after the first carrier C1 is de-bonded as shown in FIG. 1G, the plurality of metal patterns MP may be removed (e.g., through etching) before forming the plurality of first connectors CT1 (as shown in FIG. 1H) on the interconnect structure ITC to expose the plurality of polymer patterns PP. In such embodiments, the first encapsulant EN1 is in direct contact with the plurality of polymer patterns PP.

A method of forming a semiconductor package (e.g., the semiconductor package PKG in FIG. 1P or the semiconductor package PKG′ in FIG. 2) according to some embodiments of the disclosure includes an act/step of forming a plurality of mark structures. FIG. 1A to FIG. 1B illustrate a cross-sectional partial view corresponding to some embodiments of this act/step.

The method of forming the semiconductor package according to some embodiments of the disclosure further includes an act/step of forming an interconnect structure on the plurality of mark structures, wherein the interconnect structure includes a plurality of vias and a plurality of lines stacked alternately and electrically connected to each other and embedded by a plurality of polymer layers, the plurality of mark structures are embedded in a first polymer layer among the plurality of polymer layers closest to the plurality of dies, and the plurality of mark structures are electrically insulated from the plurality of vias and the plurality of lines. FIG. 1C to FIG. 1G illustrate a cross-sectional partial view corresponding to some embodiments of this act/step.

The method of forming the semiconductor package according to some embodiments of the disclosure further includes an act/step of forming a plurality of first connectors on a first side of the interconnect structure, wherein the plurality of mark structures are electrically insulated from the plurality of first connectors. FIG. 1H illustrates a cross-sectional partial view corresponding to some embodiments of this act/step.

The method of forming the semiconductor package according to some embodiments of the disclosure further includes an act/step of bonding a plurality of dies to the plurality of first connectors. FIG. 1I illustrates a cross-sectional partial view corresponding to some embodiments of this act/step.

The method of forming the semiconductor package according to some embodiments of the disclosure further includes an act/step of encapsulating the plurality of dies with a first encapsulant. FIG. 1J illustrates a cross-sectional partial view corresponding to some embodiments of this act/step.

The method of forming the semiconductor package according to some embodiments of the disclosure further includes an act/step of forming a plurality of second connectors on a second side of the interconnect structure. FIG. 1K to FIG. 1L illustrate a cross-sectional partial view corresponding to some embodiments of this act/step.

The method of forming the semiconductor package according to some embodiments of the disclosure further includes an act/step of bonding a plurality of circuit boards to the plurality of second connectors. FIG. 1M illustrates a cross-sectional partial view corresponding to some embodiments of this act/step.

The method of forming the semiconductor package according to some embodiments of the disclosure further includes an act/step of encapsulating the plurality of circuit boards with a second encapsulant. FIG. 1N illustrates a cross-sectional partial view corresponding to some embodiments of this act/step.

The method of forming the semiconductor package according to some embodiments of the disclosure further includes an act/step of performing a singulation process. FIG. 1O illustrates a cross-sectional partial view corresponding to some embodiments of this act/step.

In some embodiments, as shown in FIG. 1A to FIG. 1B, forming the plurality of mark structures includes: forming a seed layer on a first carrier; forming a plurality of polymer patterns on the seed layer; and patterning the seed layer with the plurality of polymer patterns to form a plurality of metal patterns. In some embodiments, as shown in FIG. 1F to FIG. 1G, the method of forming the semiconductor package further includes: attaching the interconnect structure to a second carrier and debonding the first carrier before forming the plurality of first connectors on the first side of the interconnect structure, wherein the plurality of metal patterns are exposed when the first carrier is de-bonded. In some embodiments, the method of forming the semiconductor package further includes: removing the plurality of metal patterns before forming the plurality of first connectors (as shown in FIG. 1H) on the first side of the interconnect structure to expose the plurality of polymer patterns. In some embodiments, as shown in FIG. 1C to FIG. 1F, forming the interconnect structure includes: forming a first redistribution layer structure on the plurality of mark structures; forming a plurality of bridge dies and a plurality of conductive vias on the first redistribution layer; and forming a second redistribution layer structure on the plurality of bridge dies and the plurality of conductive vias. In some embodiments, the first polymer layer is patterned using two exposure systems with different field of views and two different masks, and the two masks are aligned according to the plurality of mark structures.

Based on the above discussions, it can be seen that the present disclosure offers various advantages. It is understood, however, that not all advantages are necessarily discussed herein, and other embodiments may offer different advantages, and that no particular advantage is required for all embodiments.

According to some embodiments, a semiconductor package includes an interconnect structure, a plurality of first connectors, a die, a plurality of second connectors, a circuit board and a mark structure. The interconnect structure includes a plurality of vias and a plurality of lines stacked alternately and electrically connected to each other and embedded by a plurality of polymer layers. The plurality of first connectors are disposed on a first side of the interconnect structure. The die is bonded to the plurality of first connectors. The plurality of second connectors are disposed on a second side of the interconnect structure. The circuit board is bonded to the plurality of second connectors. The mark structure is embedded in a first polymer layer among the plurality of polymer layers closest to the die and electrically insulated from the plurality of vias, the plurality of lines and the plurality of first connectors. In some embodiments, the mark structure is a stack of two patterns respectively formed of a reflective material and a transparent material, and orthogonal projections of the two patterns are the same. In some embodiments, the two patterns are a metal pattern and a polymer pattern, and the metal pattern is closer to the die than the polymer pattern. In some embodiments, a surface of the metal pattern facing the die is leveled with a surface of the first polymer layer facing the die. In some embodiments, the mark structure includes a polymer pattern, a surface of the polymer pattern facing the die is indented from a surface of the first polymer layer facing the die, and a surface of the polymer pattern facing away from the die is indented from a surface of the first polymer layer facing away from the die. In some embodiments, the first polymer layer includes a plurality of island-shaped patterns and a plurality of frame-shaped patterns in a chip region of the semiconductor package, and the plurality of island-shaped patterns are respectively surrounded by the plurality of frame-shaped patterns. In some embodiments, a thickness of the frame-shaped patterns is larger than a thickness of the island-shaped patterns, and a thickness of the mark structure is smaller than the thickness of the island-shaped patterns.

According to some embodiments, a semiconductor package includes an interconnect structure, a plurality of first connectors, a die, a plurality of second connectors, a circuit board and a mark structure. The interconnect structure includes a plurality of vias and a plurality of lines stacked alternately and electrically connected to each other and embedded by a plurality of polymer layers. The plurality of first connectors are disposed on a first side of the interconnect structure. The die is bonded to the plurality of first connectors. The plurality of second connectors are disposed on a second side of the interconnect structure. The circuit board is bonded to the plurality of second connectors. The mark structure is embedded in a first polymer layer among the plurality of polymer layers closest to the die, wherein the mark structure includes a polymer pattern having a thickness smaller than a thickness of the first polymer layer. In some embodiments, the mark structure further includes a metal pattern, and orthogonal projections of the metal pattern and the polymer pattern are the same. In some embodiments, a surface of the metal pattern facing the die is leveled with a surface of the first polymer layer facing the die. In some embodiments, the first polymer layer includes a plurality of island-shaped patterns and a plurality of frame-shaped patterns in a chip region of the semiconductor package, and the plurality of island-shaped patterns are respectively surrounded by the plurality of frame-shaped patterns. In some embodiments, a thickness of the frame-shaped patterns is larger than a thickness of the island-shaped patterns, and the thickness of the polymer pattern is smaller than the thickness of the island-shaped patterns. In some embodiments, the semiconductor package has a chip region and a periphery region surrounding the chip region, and the mark structure is located in the chip region, the periphery region or a combination of the above. In some embodiments, the interconnect structure includes a first redistribution layer structure, a plurality of bridge dies, a plurality of conductive vias, and a second redistribution layer structure, and wherein: the plurality of bridge dies and the plurality of conductive vias are located between the first redistribution layer structure and the second redistribution layer structure, the plurality of first connectors are located between the first redistribution layer structure and the die, and the plurality of second connectors are located between the second redistribution layer structure and the circuit board.

According to some embodiments, a method of forming a semiconductor package includes: forming a plurality of mark structures; forming an interconnect structure on the plurality of mark structures, wherein the interconnect structure includes a plurality of vias and a plurality of lines stacked alternately and electrically connected to each other and embedded by a plurality of polymer layers, the plurality of mark structures are embedded in a first polymer layer among the plurality of polymer layers closest to the plurality of dies, and the plurality of mark structures are electrically insulated from the plurality of vias and the plurality of lines; forming a plurality of first connectors on a first side of the interconnect structure, wherein the plurality of mark structures are electrically insulated from the plurality of first connectors; bonding a plurality of dies to the plurality of first connectors; encapsulating the plurality of dies with a first encapsulant; forming a plurality of second connectors on a second side of the interconnect structure; bonding a plurality of circuit boards to the plurality of second connectors; encapsulating the plurality of circuit boards with a second encapsulant; and performing a singulation process. In some embodiments, forming the plurality of mark structures includes: forming a seed layer on a first carrier; forming a plurality of polymer patterns on the seed layer; and patterning the seed layer with the plurality of polymer patterns to form a plurality of metal patterns. In some embodiments, the method of forming the semiconductor package further includes: attaching the interconnect structure to a second carrier and debonding the first carrier before forming the plurality of first connectors on the first side of the interconnect structure, wherein the plurality of metal patterns are exposed when the first carrier is de-bonded. In some embodiments, the method of forming the semiconductor package further includes: removing the plurality of metal patterns before forming the plurality of first connectors on the first side of the interconnect structure to expose the plurality of polymer patterns. In some embodiments, forming the interconnect structure includes: forming a first redistribution layer structure on the plurality of mark structures; forming a plurality of bridge dies and a plurality of conductive vias on the first redistribution layer; and forming a second redistribution layer structure on the plurality of bridge dies and the plurality of conductive vias. In some embodiments, the first polymer layer is patterned using two exposure systems with different field of views and two different masks, and the two masks are aligned according to the plurality of mark structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interconnect structure comprising a plurality of vias and a plurality of lines stacked alternately and electrically connected to each other and embedded by a plurality of polymer layers;
a plurality of first connectors disposed on a first side of the interconnect structure;
a die bonded to the plurality of first connectors;
a plurality of second connectors disposed on a second side of the interconnect structure;
a circuit board bonded to the plurality of second connectors; and
a mark structure embedded in a first polymer layer among the plurality of polymer layers closest to the die and electrically insulated from the plurality of vias, the plurality of lines and the plurality of first connectors.

2. The semiconductor package as claimed in claim 1, wherein the mark structure is a stack of two patterns respectively formed of a reflective material and a transparent material, and orthogonal projections of the two patterns are the same.

3. The semiconductor package as claimed in claim 2, wherein the two patterns are a metal pattern and a polymer pattern, and the metal pattern is closer to the die than the polymer pattern.

4. The semiconductor package as claimed in claim 3, wherein a surface of the metal pattern facing the die is leveled with a surface of the first polymer layer facing the die.

5. The semiconductor package as claimed in claim 1, wherein the mark structure comprises a polymer pattern,
a surface of the polymer pattern facing the die is indented from a surface of the first polymer layer facing the die, and
a surface of the polymer pattern facing away from the die is indented from a surface of the first polymer layer facing away from the die.

6. The semiconductor package as claimed in claim 1, wherein the first polymer layer comprises a plurality of island-shaped patterns and a plurality of frame-shaped patterns in a chip region of the semiconductor package, and the plurality of island-shaped patterns are respectively surrounded by the plurality of frame-shaped patterns.

7. The semiconductor package as claimed in claim 6, wherein a thickness of the frame-shaped patterns is larger than a thickness of the island-shaped patterns, and a thickness of the mark structure is smaller than the thickness of the island-shaped patterns.

8. A semiconductor package, comprising:
an interconnect structure comprising a plurality of vias and a plurality of lines stacked alternately and electrically connected to each other and embedded by a plurality of polymer layers;
a plurality of first connectors disposed on a first side of the interconnect structure;
a die bonded to the plurality of first connectors;
a plurality of second connectors disposed on a second side of the interconnect structure;
a circuit board bonded to the plurality of second connectors; and
a mark structure embedded in a first polymer layer among the plurality of polymer layers closest to the die, wherein the mark structure comprises a polymer pattern having a thickness smaller than a thickness of the first polymer layer.

9. The semiconductor package as claimed in claim 8, wherein the mark structure further comprises a metal pattern, and orthogonal projections of the metal pattern and the polymer pattern are the same.

10. The semiconductor package as claimed in claim 9, wherein a surface of the metal pattern facing the die is leveled with a surface of the first polymer layer facing the die.

11. The semiconductor package as claimed in claim 8, wherein the first polymer layer comprises a plurality of island-shaped patterns and a plurality of frame-shaped patterns in a chip region of the semiconductor package, and the plurality of island-shaped patterns are respectively surrounded by the plurality of frame-shaped patterns.

12. The semiconductor package as claimed in claim 11, wherein a thickness of the frame-shaped patterns is larger than a thickness of the island-shaped patterns, and the thickness of the polymer pattern is smaller than the thickness of the island-shaped patterns.

13. The semiconductor package as claimed in claim 8, wherein the semiconductor package has a chip region and a periphery region surrounding the chip region, and the mark structure is located in the chip region, the periphery region or a combination of the above.

14. The semiconductor package as claimed in claim 8, wherein the interconnect structure comprises a first redistribution layer structure, a plurality of bridge dies, a plurality of conductive vias, and a second redistribution layer structure, and wherein:
the plurality of bridge dies and the plurality of conductive vias are located between the first redistribution layer structure and the second redistribution layer structure,
the plurality of first connectors are located between the first redistribution layer structure and the die, and
the plurality of second connectors are located between the second redistribution layer structure and the circuit board.

15. A method of forming a semiconductor package, comprising:
forming a plurality of mark structures;
forming an interconnect structure on the plurality of mark structures, wherein the interconnect structure comprises a plurality of vias and a plurality of lines stacked alternately and electrically connected to each other and embedded by a plurality of polymer layers;
forming a plurality of first connectors on a first side of the interconnect structure, wherein the plurality of mark structures are electrically insulated from the plurality of first connectors;
bonding a plurality of dies to the plurality of first connectors, wherein the plurality of mark structures are embedded in a first polymer layer among the plurality of polymer layers closest to the plurality of dies, and the plurality of mark structures are electrically insulated from the plurality of vias and the plurality of lines;
encapsulating the plurality of dies with a first encapsulant;
forming a plurality of second connectors on a second side of the interconnect structure;
bonding a plurality of circuit boards to the plurality of second connectors;
encapsulating the plurality of circuit boards with a second encapsulant; and
performing a singulation process.

16. The method of forming the semiconductor package as claimed in claim 15, wherein forming the plurality of mark structures comprises:
forming a seed layer on a first carrier;
forming a plurality of polymer patterns on the seed layer; and
patterning the seed layer with the plurality of polymer patterns to form a plurality of metal patterns.

17. The method of forming the semiconductor package as claimed in claim 16, further comprising:
attaching the interconnect structure to a second carrier and debonding the first carrier before forming the plurality of first connectors on the first side of the interconnect structure, wherein the plurality of metal patterns are exposed when the first carrier is de-bonded.

18. The method of forming the semiconductor package as claimed in claim 17, further comprising:
removing the plurality of metal patterns before forming the plurality of first connectors on the first side of the interconnect structure to expose the plurality of polymer patterns.

19. The method of forming the semiconductor package as claimed in claim 15, wherein forming the interconnect structure comprises:
forming a first redistribution layer structure on the plurality of mark structures;
forming a plurality of bridge dies and a plurality of conductive vias on the first redistribution layer; and
forming a second redistribution layer structure on the plurality of bridge dies and the plurality of conductive vias.

20. The method of forming the semiconductor package as claimed in claim 15, wherein the first polymer layer is patterned using two exposure systems with different field of views and two different masks, and the two masks are aligned according to the plurality of mark structures.
